(19) United States
(12) Patent Application Publication
(10) Pub. No.: US 2026/0094797 A1
(43) Pub. Date: Apr. 2, 2026

(54) SPUTTERING APPARATUS, APPARATUS FOR MANUFACTURING MAGNETIC RECORDING MEDIUM, THIN FILM FORMING METHOD, AND METHOD FOR MANUFACTURING MAGNETIC RECORDING MEDIUM

(71) Applicant: Resonac Hard Disk Corporation, Chiba (JP)

(72) Inventors: Takumi SUGAHARA, Chiba (JP); Haruhisa OHASHI, Chiba (JP)

(21) Appl. No.: 19/331,235

(22) Filed: Sep. 17, 2025

(30) Foreign Application Priority Data
Sep. 27, 2024 (JP) 2024-168485

(51) Int. Cl. H01J 37/34; C23C 14/35; G11B 5/851

(52) U.S. Cl. CPC H01J 37/3461; C23C 14/35; G11B 5/851; H01J 37/3455; H01J 2237/332

(57) ABSTRACT

A sputtering apparatus forms a thin film by depositing sputtered particles of a target on a substrate, using a magnetic field generated from a back surface side of the target toward the substrate provided to face a front surface of the target. The sputtering apparatus has a magnetic field generator provided on the back surface of the target, a rotor configured to rotate the magnetic field generator, and a cylindrical sputter adjustment member provided between the target and the substrate on a center axis connecting a center of the target and a center position of the substrate. The sputter adjustment member is made of a metal, and includes a hole located at a position including the center axis.

### CROSS-REFERENCE TO RELATED APPLICATIONS

This application is based upon and claims priority to Japanese Patent Application No. 2024-168485, filed on Sep. 27, 2024, the entire contents of which are incorporated herein by reference.

### FIELD

Certain aspects of the embodiments discussed herein are related to sputtering apparatuses, apparatuses for manufacturing magnetic recording media, thin film forming methods, and methods for manufacturing magnetic recording media.

### BACKGROUND

A magnetic recording medium is configured by stacking a plurality of thin films, such as a seed layer, an underlayer, and a magnetic layer on a nonmagnetic substrate. Each layer constituting the magnetic recording medium is formed mainly using a sputtering apparatus or the like. The sputtering apparatus may be an apparatus for forming a film on a substrate by sputtering a target material using plasma, or the like.

An example of the sputtering apparatus for forming the film on the substrate by sputtering the target material using the plasma includes a plurality of antennas that generates the plasma inside a vacuum chamber accommodating the substrate, a reciprocating scanning mechanism that reciprocates and scans the substrate along a scanning direction in which the plurality of antennas is arranged, and a mask for controlling a film thickness provided on one end or both ends in the scanning direction of the substrate in a film forming region defined between the target and the substrate. For example, Japanese Laid-Open Patent Publication No. 2022-117694 proposes an example of such a sputtering apparatus.

In the sputtering apparatus proposed in Japanese Laid-Open Patent Publication No. 2022-117694, the mask for controlling the film thickness is provided on one end or both ends in the scanning direction of the substrate in the film forming region inside the vacuum chamber, and sputtered particles from the target are deposited on the substrate using the plasma while the reciprocating scanning mechanism reciprocates and scans the substrate along the scanning direction parallel to the target. Hence, a film thickness distribution along a direction perpendicular to the scanning direction of the substrate can be made uniform.

However, Japanese Laid-Open Patent Publication No. 2022-117694 only proposes making uniform the film thickness distribution along the direction perpendicular to the scanning direction of the substrate, and does not propose or suggest making the film thickness distribution on the entire surface of the substrate uniform including the scanning direction of the substrate.

The plasma generated inside the vacuum chamber varies between a region directly below the antenna and other regions, and a plasma distribution tends to become uneven. In the sputtering apparatus proposed in Japanese Laid-Open Patent Publication No. 2022-117694, the mask for controlling the film thickness is provided at a position deviated from the region immediately below the antenna, and the sputtered particles are deposited on the substrate while the reciprocating scanning mechanism reciprocates and scans the substrate along the scanning direction parallel to the target. Consequently, there is a problem that it is difficult to make the film thickness distribution on the entire surface of the substrate uniform including the scanning direction of the substrate.

### SUMMARY

Accordingly, it is an object in one aspect of the embodiments to provide a sputtering apparatus and a thin film forming method capable of improving a uniformity of an in-plane film thickness distribution of a thin film formed on a substrate.

According to one aspect of the embodiments, a sputtering apparatus is configured to form a thin film by depositing sputtered particles of a target on a substrate, using a magnetic field generated from a back surface side of the target toward the substrate provided to face a front surface of the target, and includes a magnetic field generator provided on the back surface of the target; a rotor configured to rotate the magnetic field generator; and a cylindrical sputter adjustment member provided between the target and the substrate on a center axis connecting a center of the target and a center position of the substrate, wherein the sputter adjustment member is made of a metal, and includes a hole located at a position including the center axis.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a partial cross sectional view illustrating an example of a sputtering apparatus according to an embodiment of the present disclosure;

FIG. 2 is a front view of the sputtering apparatus illustrated in FIG. 1;

FIG. 3 is a plan view of a gas inlet pipe of the sputtering apparatus;

FIG. 4A is a diagram illustrating an example of a state of magnetic field lines generated by a magnet assembly and passing through a surface of a substrate to be processed;

FIG. 4B is a diagram illustrating an example of a state of magnetic field lines generated by the magnet assembly and passing through the surface of the substrate to be processed when the magnet assembly is viewed in a direction of a center axis;

FIG. 5 is a perspective view illustrating an example of a configuration of a sputter adjustment member;

FIG. 6 is a diagram for explaining a state where an induced current is generated, and a plasma density near an inner peripheral portion of the substrate to be processed decreases;

FIG. 7 is a diagram illustrating a carrier and a transport mechanism viewed in a direction perpendicular to a transport direction;

FIG. 8 is a diagram illustrating the carrier and the transport mechanism viewed along the transport direction;

FIG. 9 is a diagram illustrating an example of a configuration of an in-line film forming apparatus to which a sputtering apparatus according to the embodiment of the present disclosure is applied;

FIG. 10 is a cross sectional view illustrating an example of a layer configuration of a magnetic recording medium manufactured using an apparatus for manufacturing the magnetic recording medium;

FIG. 11 is a perspective view illustrating an example of a configuration of a magnetic storage apparatus; and

FIG. 12 is a diagram illustrating measurement results of a thickness measured at predetermined lengths in a radial direction on a front surface and a back surface of samples of an exemplary implementation and a comparative example.

### DESCRIPTION OF EMBODIMENTS

Hereinafter, embodiments of the present disclosure will be described in detail with reference to the drawings. In order to facilitate understanding of the description, in the drawings, those constituent elements that are the same are designated by the same reference numerals, and a redundant description thereof will be omitted. A scale of each member in the drawings may be different from an actual scale. In the present specification, a numerical range from A to B includes a lower limit value A and an upper limit value B, unless indicated otherwise.

A sputtering apparatus according to an embodiment of the present disclosure is an apparatus that forms a thin film by causing sputtered particles of a target to deposit on a substrate, using a magnetic field generated from a back surface side of the target toward the substrate provided to face a front surface of the target. The sputtering apparatus according to the present embodiment includes a magnetic field generator provided on the back surface of the target, a rotator unit configured to rotate the magnetic field generator, and a cylindrical sputter adjustment member. The sputter adjustment member is provided between the target and the substrate, on a center axis connecting a center of the target and a center position of the substrate. The sputter adjustment member is made of a metal, and a hole of the sputter adjustment member is provided so as to include the center axis.

In the sputtering apparatus according to the present embodiment, the cylindrical sputter adjustment member made of the metal is provided between the target and the substrate, on the center axis connecting the center of the target and the center position of the substrate, so that the hole of the sputter adjustment member includes the center axis. Hence, the sputtering apparatus according to the present embodiment can vary a magnetic field passing through the hole of the sputter adjusting member, and decrease a density of plasma generated on an inner peripheral portion of the substrate. For this reason, it is possible to suppress an increase in an amount of sputtered particles deposited on the inner peripheral portion of the substrate, and improve a uniformity of an in-plane film thickness distribution of the thin film formed on the substrate.

The inner peripheral portion of the substrate is a region (or an area) including a central portion of a principal surface of the substrate and a vicinity of the central portion. The inner peripheral portion of the substrate may be a region (or an area) from the central portion of the principal surface of the substrate to a middle between the central portion and an outer periphery of the principal surface of the substrate. In a case where the principal surface of the substrate is circular with an opening at the center, the inner peripheral portion of the substrate is a region (or an area) including an inner periphery of the principal surface of the substrate and a vicinity of the inner periphery, and may be a region (or an area) from the inner periphery of the principal surface of the substrate to a middle between the inner periphery and the outer periphery of the principal surface of the substrate.

A thin film forming method according to the present embodiment includes a thin film forming process (or step) of forming a thin film by depositing sputtered particles of a target onto a substrate, using a magnetic field generated from a back surface side of the target toward the substrate provided to face a front surface of the target. The thin film forming process rotates a magnetic field generator provided on the back surface of the target, to vary a magnetic field passing through a hole provided in a cylindrical sputter adjustment member made of a metal so as to include a center axis of the sputter adjustment member, wherein the cylindrical sputter adjustment member is provided between the target and the substrate on the center axis connecting a center of the target and a center position of the substrate.

During the thin film forming process of the thin film forming method according to the present embodiment, the cylindrical sputter adjustment member made of the metal is provided between the target and the substrate on the center axis connecting the center of the target and the center position of the substrate, so that the hole of the sputter adjustment member includes the center axis. Accordingly, because the thin film forming method according to the present embodiment can vary the magnetic field passing through the hole of the sputter adjusting member, and decrease a density of plasma generated on an inner peripheral portion of the substrate, it is possible to suppress an increase in an amount of sputtered particles deposited on the inner peripheral portion of the substrate, and improve a uniformity of an in-plane film thickness distribution of the thin film formed on the substrate.

The present disclosure can provide the following configurations.

[1] A sputtering apparatus configured to form a thin film by depositing sputtered particles of a target on a substrate, using a magnetic field generated from a back surface side of the target toward the substrate provided to face a front surface of the target, the sputtering apparatus comprising:
a magnetic field generator provided on the back surface of the target;
a rotor configured to rotate the magnetic field generator; and
a cylindrical sputter adjustment member provided between the target and the substrate on a center axis connecting a center of the target and a center position of the substrate,
wherein the sputter adjustment member is made of a metal, and includes a hole located at a position including the center axis.

[2] The sputtering apparatus according to [1], wherein the sputter adjustment member is composed of a ring-shaped member including a metal wire wound in a ring shape.

[3] The sputtering apparatus according to [1] or [2], wherein an inner diameter of the sputter adjustment member is smaller than an outer diameter of the substrate.

[4] The sputtering apparatus according to any one of [1] to [3], wherein the hole of the sputter adjustment member is provided at a central portion of the target when viewed in a direction of the center axis.

[5] The sputtering apparatus according to any one of [1] to [4], wherein the thin film constitutes a magnetic recording medium.

[6] An apparatus for manufacturing a magnetic recording medium, comprising:
the sputtering apparatus according to any one of [1] to [5].

[7] A thin film forming method comprising:
forming a thin film by depositing sputtered particles of a target on a substrate, using a magnetic field generated from a back surface side of the target toward the substrate provided to face a front surface of the target,
wherein the forming includes rotating a magnetic field generator provided on the back surface of the target to vary a magnetic field passing through a hole in a cylindrical sputter adjustment member provided between the target and the substrate on a center axis connecting a center of the target and a center position of the substrate, the sputter adjustment member being made of a metal and includes the hole located at a position including the center axis.

[8] A method for manufacturing a magnetic recording medium, comprising:
forming the thin film on a surface of the substrate, as a layer constituting a magnetic recording medium, using the thin film forming method according to [7].

### <Sputtering Apparatus>

A sputtering apparatus according to the present embodiment will be described. In the present embodiment, as an example, the sputtering apparatus according to the present embodiment is used to form one layer constituting a magnetic recording medium provided in a hard disk drive (HDD). The HDD is an example of a magnetic storage apparatus (or a magnetic recording and/or reproducing apparatus).

Examples of the sputtering apparatus include a magnetron sputtering apparatus, a direct current (DC) sputtering apparatus, a radio frequency (RF) sputtering apparatus, a microwave frequency (MW) sputtering apparatus, a reactive sputtering apparatus, or the like, for example. In the present embodiment, a case where the sputtering apparatus is a magnetron sputtering apparatus will be described as an example.

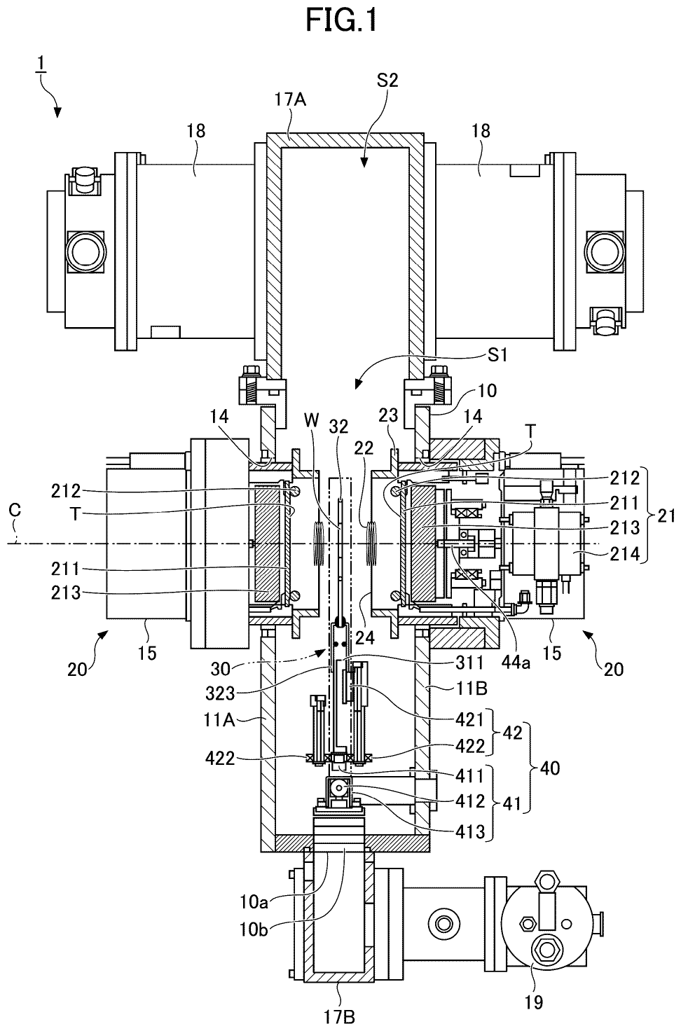

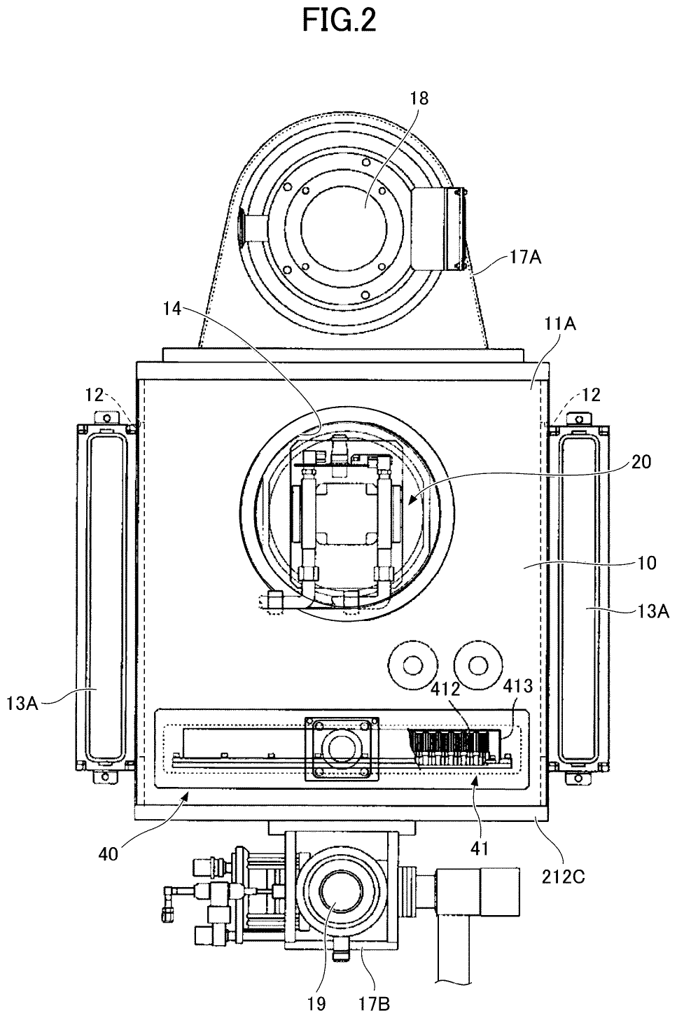

FIG. 1 is a partial cross sectional view illustrating an example of the sputtering apparatus according to the present embodiment, and FIG. 2 is a front view of the sputtering apparatus illustrated in FIG. 1. As illustrated in FIG. 1, a sputtering apparatus 1 according to the present embodiment constitutes one processing chamber of an apparatus for manufacturing a magnetic recording medium. The apparatus for manufacturing the magnetic recording medium performs a film forming process or the like while sequentially transporting a substrate W for film deposition (or a substrate W to be processed) among a plurality of chambers which will be described later.

The sputtering apparatus 1 includes a reaction chamber 10 in which the substrate W for film deposition (hereinafter simply referred to as the “substrate W”) is disposed, a processing module 20 for performing a film forming process or the like on the substrate W, a carrier 30 attached with the substrate W, and a transport mechanism 40 for transporting the carrier 30 among the plurality of chambers. The sputtering apparatus 1 forms a thin film by depositing sputtered particles of a target T to on the substrate W, using a magnetic field generated from a back surface side of the target T toward the substrate W that is provided to face a front surface of the target T inside the reaction chamber 10.

### (Reaction Chamber)

As illustrated in FIG. 1, the reaction chamber 10 is a vacuum chamber that is hermetically sealed by pressure-resistant partitions in order to create a high vacuum state inside the reaction chamber 10. The reaction chamber 10 includes a front partition 11A and a rear partition 11B opposing each other, and a flat internal space S1 is formed between the front partition 11A and the rear partition 11B.

As illustrated in FIG. 2, the reaction chamber 10 includes substrate loading and/or unloading ports 12 through which the carrier 30 passes, and a pair of gate valves 13A for opening and closing the substrate loading and/or unloading ports 12, at front and rear in a transport direction of the carrier 30, respectively. That is, the reaction chamber 10 is connected to adjacent chambers via the gate valves 13A. When the sputtering apparatus 1 is applied to the apparatus for manufacturing the magnetic recording medium, the sputtering apparatus 1 moves the carrier 30 between the adjacent reaction chambers 10 by passing the carrier 30 through the substrate loading and/or unloading ports 12.

As illustrated in FIG. 1, the reaction chamber 10 has openings 14 facing an interior of the reaction chamber 10 in the front partition 11A and the rear partition 11B of the reaction chamber 10. The openings 14 are formed in an elliptical shape having a size sufficient to dispose the processing module 20 at a position opposing both surfaces of the substrate W attached to the carrier 30.

The reaction chamber 10 may include a cylindrical housing 15 that hermetically seals peripheries of the openings 14 in the front partition 11A and the rear partition 11B, respectively. The housing 15 can accommodate a cathode unit 21 or the like of the processing module 20 inside the housing 15. The front partition 11A and the rear partition 11B may be attached to the reaction chamber 10 so as to be openable and closable with respect to the reaction chamber 10, in order to enable opening of the reaction chamber 10 during maintenance or the like.

The sputtering apparatus 1 includes an upper pump chamber 17A above the reaction chamber 10, and a lower pump chamber 17B below the reaction chamber 10.

The upper pump chamber 17A is hermetically formed by pressure-resistant partitions. The upper pump chamber 17A is connected to an upper portion of the reaction chamber 10 by a fastening member. The upper pump chamber 17A is formed so as to include an internal space S2 continuous with the internal space S1 of the reaction chamber 10.

The lower pump chamber 17B is hermetically formed by pressure-resistant partitions. The lower pump chamber 17B is connected to a lower portion of the reaction chamber 10. The lower pump chamber 17B communicates with the internal space S1 of the reaction chamber 10 through an opening 10b formed in a bottom wall 10a of the reaction chamber 10.

The sputtering apparatus 1 includes first vacuum pumps 18 disposed above the reaction chamber 10 and a second vacuum pump 19 disposed below the reaction chamber 10, as decompression exhaust mechanisms for evacuating the reaction chamber 10 under reduced pressure.

The first vacuum pumps 18 are attached through the upper pump chamber 17A disposed above the reaction chamber 10. The first vacuum pumps 18 are attached to both side surfaces of the upper pump chamber 17A in a state opposing each other. Turbo molecular pumps or the like can be used for the first vacuum pumps 18. The turbo molecular pump has a configuration which does not use a lubricant oil, and thus has a high level of cleanliness and a high exhaust speed. Hence, a high degree of vacuum can easily be obtained, and the turbo molecular pump is suitable for exhausting a highly reactive gas.

The second vacuum pump 19 is attached through the lower pump chamber 17B disposed below the reaction chamber 10. The second vacuum pump 19 is connected to a side surface of the lower pump chamber 17B. A cryopump or the like can be used for the second vacuum pump 19. The cryopump can obtain a high degree of vacuum by generating extremely low temperatures and causing condensation or cryo-adsorption of an internal gas. The cryopump is preferable because the cryopump is superior compared to the turbo molecular pump in terms of an exhaust speed and cleanliness.

The sputtering apparatus 1 has a configuration capable of reducing the pressure inside the reaction chamber 10, exhausting the gas introduced into the reaction chamber 10, or the like while controlling driving of the first vacuum pumps 18 and the second vacuum pump 19.

In the present embodiment, two first vacuum pumps 18 are disposed on both side surfaces of the reaction chamber 10, and one second vacuum pump 19 is disposed below the reaction chamber 10, but the arrangement, the number, or the like of the first vacuum pumps 18 and the second vacuum pump 19 may be modified, as appropriate. For example, when the number of the first vacuum pumps 18 and the number of the second vacuum pumps 19 are increased, a time required to evacuate the reaction chamber 10 can be reduced. On the other hand, when the number of the first vacuum pumps 18 and the number of the second vacuum pumps 19 are decreased, the sputtering apparatus 1 can be downsized, and an increase in power consumption can be suppressed.

In addition, the cryopump used for the second vacuum pump 19 has a configuration for storing the gas therein, unlike the turbo molecular pump having a configuration for discharging the gas to the outside. For this reason, in a case where the gas introduced into the reaction chamber 10 is a highly reactive gas, it is desirable to exhaust the gas to the outside of the reaction chamber 10 using the turbo molecular pumps as the first vacuum pumps 18. Accordingly, the inside of the reaction chamber 10 can be kept clean while suppressing the corrosion of metal components such as a main bearing 421 and a sub bearing 422 constituting the transport mechanism 40 due to a flow of the gas after the reaction to the lower portion of a reaction space R. The turbo molecular pump may be used as the second vacuum pump 19 in place of the cryopump.

### (Processing Module)

As illustrated in FIG. 1, the processing module 20 is provided to oppose the front partition 11A and the rear partition 11B of the reaction chamber 10, respectively, and perform the thin film forming process on both surfaces of the substrate W held by the carrier 30.

The processing module 20 is disposed to face both surfaces of the substrate W held by a holder 32 of the carrier 30. The processing module 20 includes the cathode unit 21 for generating sputtering discharge, a sputter adjustment member 22, and a support member 23.

The cathode unit 21 includes a backing plate 211 attached with the target T, a gas inlet pipe 212 which forms a gas introduction section, a magnet assembly 213 which forms a magnetic field generator that generates a magnetic field, and a drive motor 214 which forms a rotating section attached with the magnet assembly 213.

The backing plate 211 is disposed inside the reaction chamber 10 to face the surface of the substrate W held by the carrier 30. The target T is attached to a front surface of the backing plate 211. The front surface of the backing plate 211 faces the substrate W. The backing plate 211 is electrically connected to an external power supply (not illustrated), and is configured to apply a voltage from the external power supply to the target T via the backing plate 211.

Examples of the external power supply include an AC power supply, such as a radio frequency (RF) power supply and a microwave power supply, a DC power supply, or the like, for example. A current supplied from the external power supply to the target T may be either a DC current or an AC current. In a case where the external power supply is a high-frequency power supply or a microwave power supply, for example, a high-frequency voltage or a microwave voltage is applied to the target T from the external power supply.

Specifically, in the sputtering apparatus 1, two backing plates 211 are disposed inside the reaction chamber 10 so as to face both surfaces of the substrate W held by the carrier 30, respectively, in order to perform the film forming process or the like on both surfaces of the substrate W simultaneously. The targets T are attached to the front surfaces of the two backing plates 211 facing the substrate W, respectively. The voltage from the external power supply is applied to the targets T as a direct current or an alternating current via the backing plates 211, respectively.

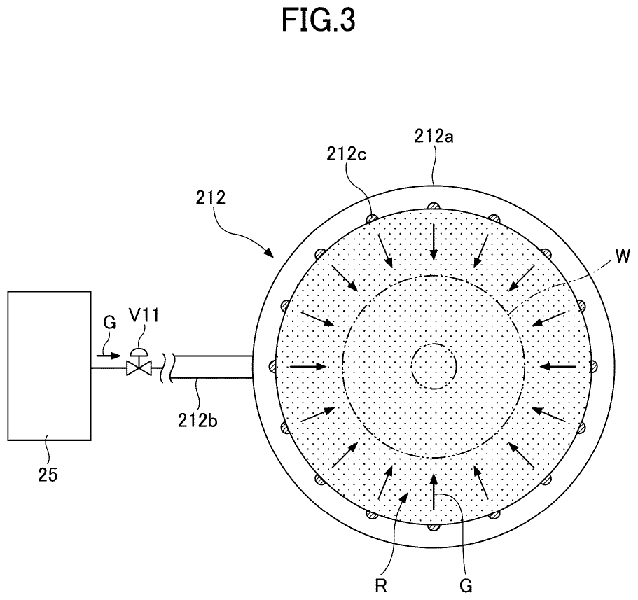

The gas inlet pipe 212 introduces a gas into the reaction chamber 10. As illustrated in FIG. 3, the gas inlet pipe 212 has an annular part 212a formed in a ring shape corresponding to the disk-shaped substrate W, and a connecting part 212b connected to the annular part 212a. The gas inlet pipe 212 is connected to a gas source 25 via the connecting part 212b. The annular part 212a is formed to surround a periphery of the reaction space R formed between the substrate W and the target T. In FIG. 3, the reaction space R is indicated by a dot pattern. Further, a plurality of gas discharge ports 212c is provided at an inner peripheral portion of the annular part 212a and arranged in a circumferential direction of the annular part 212a. The gas inlet pipe 212 is configured to discharge a gas G supplied from the gas source 25 via the plurality of gas discharge ports 212c toward the substrate W located on an inner side the gas inlet pipe 212.

A diameter of each gas discharge port 212c may be varied in order to make an amount of the gas G discharged from the gas discharge ports 212c constant. Specifically, the diameters of the gas discharge ports 212c may be increased according to distances from the connecting part 212b, so that the amount of the gas G discharged from the gas discharge ports 212c becomes constant.

Further, a regulating valve V11 may be provided in a pipe between the gas inlet pipe 212 and the gas source 25. In the sputtering apparatus 1, the opening and closing of the regulating valve V11 can be controlled, and a flow rate of the gas G supplied to the gas inlet pipe 212 can be adjusted via the regulating valve V11.

As illustrated in FIG. 1, the magnet assemblies 213 are disposed on the back surfaces of the backing plates 211, respectively. The back surfaces of the backing plates 211 are disposed opposite to the targets T, respectively. The magnet assemblies 213 generate magnetic fields from the back surface sides of the targets T toward the substrate W provided to face the front surfaces of the targets T by magnetic field lines in a closed loop.

The magnet assembly 213 includes a first magnet disposed on an outer side inside the magnet assembly 213 and having a magnetization direction perpendicular to a principal surface of the target T, and a second magnet disposed on an inner side of the first magnet and having a magnetization direction opposite to that of the first magnet. For example, the first magnet may be a magnet having a north pole (N-pole) exposed toward the backing plate 211, and the second magnet may be a magnet having a south pole (S-pole) exposed toward the backing plate 211. Permanent magnets or the like can be used for the first magnet and the second magnet, for example.

Each magnet assembly 213 is attached to a rotating shaft 44a of the drive motor 214, and is driven by the drive motor 214 to rotate on a plane parallel to the backing plate 211.

A rotational speed of each magnet assembly 213 is not particularly limited, and may be appropriately selected depending on a size of the substrate W. For example, the rotational speed may be in a range of 400 rpm to 1000 rpm, 500 rpm to 800 rpm, or 600 rpm to 700 rpm around the rotating shaft 44a.

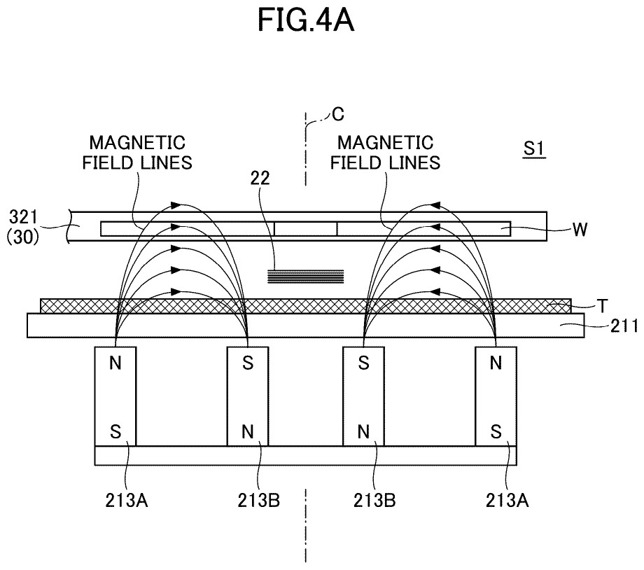

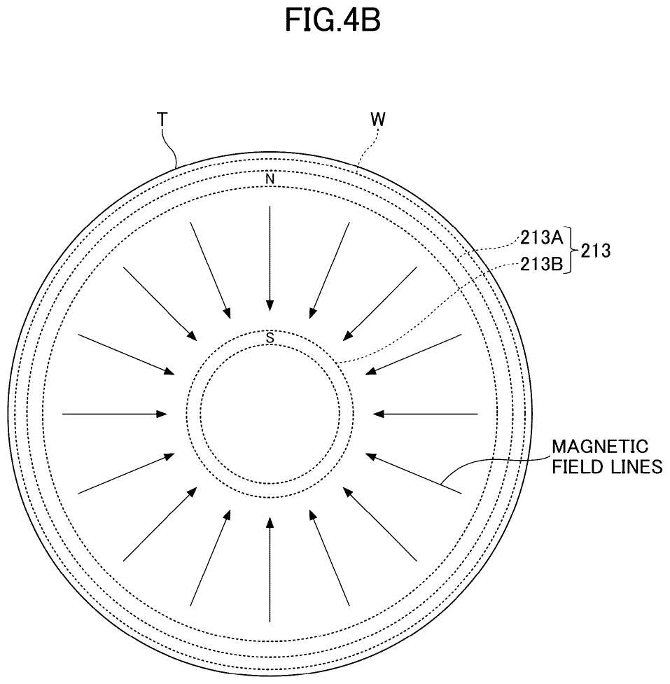

In each magnet assembly 213, the first magnet has the N-pole exposed toward the backing plate 211, and the second magnet has the S-pole exposed toward the backing plate 211. In this case, the first magnet is disposed on the outer side inside the magnet assembly 213, and the second magnet is disposed on the inner side of the first magnet, so that the magnetic field lines from the N-pole of a first magnet 213A toward the S-pole of a second magnet 213B penetrate the backing plate 211 and the target T and are generated in the internal space S1, as illustrated in FIG. 4A, for example. A part of the magnetic field lines reaches the substrate W held by the carrier 30 and passes through the substrate W in a direction substantially parallel to the surface of the substrate W, and a magnetic field substantially parallel to the surface of the substrate W is generated in a portion of the substrate W through which the magnetic field lines pass. That is, the magnetic field lines pass through the substrate W from an outer peripheral portion the inner peripheral portion of the substrate W along a radial direction of the substrate W when viewed in the plan view. As illustrated in FIG. 4B, the magnetic field is generated by the magnetic field lines from the outer peripheral portion toward the inner peripheral portion of the substrate W along the radial direction of the substrate W when viewed in the plan view. In FIG. 4A and FIG. 4B, the magnetic field lines are indicated by arrows.

The outer peripheral portion is a region (or an area) including the outer periphery of the principal surface of the substrate W and a vicinity of the outer periphery, and may be a region (or an area) other than the inner peripheral portion of the principal surface of the substrate W, or may be a region (or an area) from the middle between the inner periphery and the outer periphery of the principal surface of the substrate W to the outer periphery.

The drive motor 214 may be fixedly supported on an inner side of the housing 15, and the drive motor drives and rotates the magnet assembly 213 via the rotating shaft 44a.

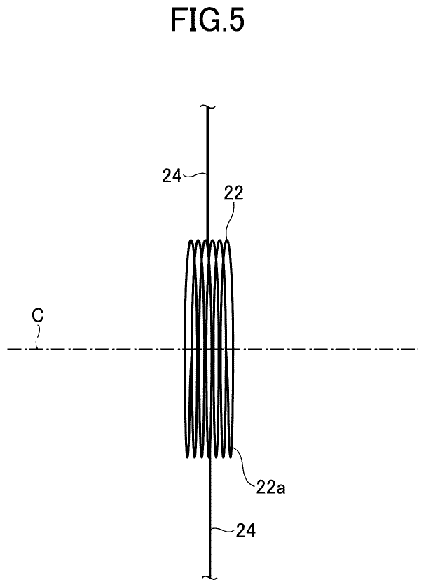

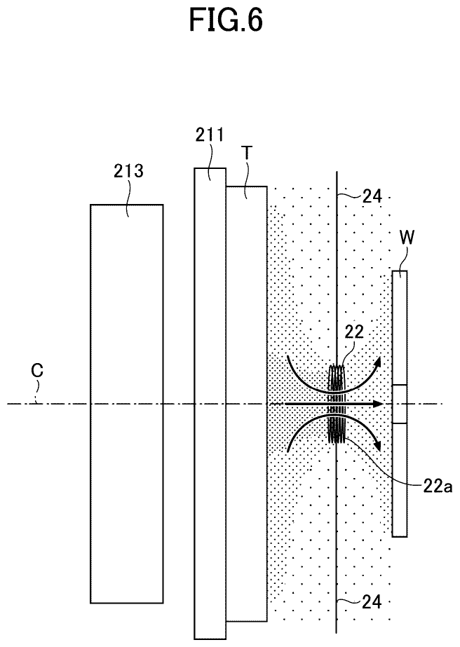

As illustrated in FIG. 1, the sputter adjustment member 22 is provided on a center axis C connecting the center of the target T and the center position of the substrate W, between the substrate W and the target T. The sputter adjustment member 22 is a cylindrical member made of a metal, and as illustrated in FIG. 5, the sputter adjustment member 22 is provided with a hole 22a that includes the center axis C. When the drive motor 214 rotates the magnet assembly 213 via the rotating shaft 44a so as to rotate in a circumferential direction of the magnet assembly 213, an amount of magnetic flux penetrating the hole 22a of the sputter adjustment member 22 varies as illustrated in FIG. 6, and an induced current flows through the sputter adjustment member 22. This induced current generates a magnetic field in the hole 22a of the sputter adjustment member 22. Because electrons of the plasma are trapped by the magnetic field generated in the hole 22a, a distribution of the plasma generated in the reaction space R can be varied, and a plasma density near the inner peripheral portion of the substrate W can be reduced, compared to a case where the sputter adjustment member 22 is not provided.

The sputter adjustment member 22 can be provided at a position where the hole 22a of the sputter adjustment member 22 includes the center axis C, by a connecting member 24 provided on a tip end of the support member 23 inside the reaction chamber 10. The method of supporting the sputter adjustment member 22 is not particularly limited, as long as the sputter adjustment member 22 is provided between the substrate W and the target T at the position where the hole 22a of the sputter adjustment member 22 includes the center axis C.

The sputter adjustment member 22 is not limited to a particular cylindrical shape as long as the shape of the sputter adjustment member 22 enables generating the induced current according to the rotation of the magnet assembly 213, varying the distribution of the plasma generated in the reaction space R, and reducing the plasma density near the inner peripheral portion of the substrate W, and the sputter adjustment member 22 may have any shape, as appropriate. The sputter adjustment member 22 is preferably composed of a ring-shaped member that is formed by winding a metal wire in a ring shape, from a viewpoint of enabling generation of the induced current according to the rotation of the magnet assembly 213 and enabling the magnetic flux to be easily varied. The sputter adjustment member 22 may be composed of a coil-shaped member that is formed by spirally winding a metal wire, in order to amplify the induced current. A coil spring or the like can be used for the coil-shaped member, for example.

The metal constituting the sputter adjustment member 22 is not particularly limited, and may be any metal that can generate the induced current according to the rotation of the magnet assembly 213 and vary the plasma distribution. For example, Cu or the like can be used for the metal constituting the sputter adjustment member 22.

The processing module 20 deposits the sputtered particles on the surface of the substrate W, using magnetron sputtering. The magnetron sputtering performs the sputtering, using the magnetic field generated from the back surface side of the target T toward the substrate W provided to face the front surface of the target T by the magnetic field lines in the closed loop. In this state, as described above and illustrated in FIG. 4A, a part of the magnetic field lines generated from the magnet assembly 213 reaches the substrate W and passes through the substrate W in the radial direction of the substrate W when viewed in the plan view, and a magnetic field substantially parallel to the surface of the substrate W is generated at a portion of the substrate W through which the magnetic field lines pass. That is, the magnetic field lines pass through the substrate W from the outer peripheral portion toward the inner peripheral portion of the substrate W along the radial direction of the substrate W when viewed in the plan view, and the magnetic field from the outer peripheral portion toward the inner peripheral portion of the substrate W along the radial direction of the substrate W is generated substantially parallel to the surface of the substrate W by the magnetic field lines. For this reason, during the thin film forming process, the density of the plasma generated inside the reaction chamber 10 tends to increase at the inner peripheral portion of the substrate W, and the amount sputtered particles from the target T deposited on the substrate W tends to increase at the inner peripheral portion of the substrate W.

As illustrated in FIG. 6, when the sputter adjustment member 22 is disposed at the center of the front surface of the target T so that the hole 22a is positioned on the center axis C, and the magnet assembly 213 attached to the back surface of the target T rotates, the magnetic field through the sputter adjustment member 22 varies, and the induced current is generated in the sputter adjustment member 22. Because the plasma generated inside the reaction chamber 10 can be dispersed from the center axis C to the periphery of the center axis C by the generation of the induced current, the plasma density near the inner peripheral portion of the substrate W decreases, and the amount of sputtered particles deposited on the inner peripheral portion of the substrate W can be suppressed. By dispersing and depositing the sputtered particles on the substrate W, the amount of sputtered particles deposited on the inner peripheral portion of the substrate W can be suppressed, and the amount of sputtered particles deposited on the outer peripheral portion of the substrate W can be increased.

The sputter adjustment member 22 can vary a magnitude of the induced current generated due to the hole 22a to vary a plasma distribution ratio, by adjusting a size or the like of the hole 22a. For this reason, the sputter adjustment member 22 can adjust the amount of sputtered particles deposited on the inner peripheral portion of the substrate W by adjusting the size or the like of the hole 22a.

The size of the hole 22a may be appropriately selected depending on a size of the inner peripheral portion of the substrate W, the amount of sputtered particles deposited on the inner peripheral portion of the substrate W, or the like.

A distance between the sputter adjustment member 22 and the front surface of the target T is not particularly limited as long as the sputter adjustment member 22 can be disposed between the target T and the substrate W, and may be appropriately selected depending on the size of the substrate W, a distance between the target T and the substrate W (or target-to-substrate distance), or the like. For example, the sputter adjustment member 22 may be provided at a distance from the target T such that the sputter adjustment member 22 does not leave a mark when the sputtering is performed on the substrate W. However, by setting the distance between the sputter adjustment member 22 and the front surface of the target T so as not to contact each other, the distribution of the plasma generated in the reaction space R can be varied by the induced current generated due to the hole 22a of the sputter adjustment member 22, and the amount of sputtered particles deposited on the inner peripheral portion of the substrate W can easily be suppressed.

An inner diameter of the sputter adjustment member 22 is preferably smaller than an outer diameter of the substrate W. For example, the inner diameter of the sputter adjustment member 22 is preferably 21% of the outer diameter of the substrate W or less, and more preferably 15% of the outer diameter of the substrate W or less. When the inner diameter of the sputter adjustment member 22 is 21% of the outer diameter of the substrate W or less, the amount of sputtered particles deposited on the inner peripheral portion of the substrate W becomes appropriate, and an in-plane film thickness distribution of the substrate W can be reduced.

The inner diameter of the sputter adjustment member 22 may be a diameter of the hole 22a in a case where the inner shape of the sputter adjustment member 22 (that is, the shape of the hole 22a) in the direction toward the center axis C is a circle, and may be an equivalent diameter, a major axis, or a major diameter in a case where the inner shape (the shape of the hole 22a) is an ellipse or a polygon such as a rectangle or the like.

The support member 23 is provided between the target T and the substrate W, and is provided along an external shape of the target T on the outer side of the target T (the side of the target T facing the magnet assembly 213) when viewed in the direction of the center axis C. The support member 23 may be composed of a cylindrical member formed to cover the external shape of the target T. The sputter adjustment member 22 is preferably provided such that the hole 22a is positioned at the central portion of the support member 23 when viewed in the direction of the center axis C. By disposing the sputter adjustment member 22 at the central portion of the support member 23 when viewed in the direction of the center axis C, the sputter adjustment member 22 can be easily provided on the support member 23 so that the hole 22a of the sputter adjustment member 22 is located at the position of the center axis C.

Further, the support member 23 is not limited to a single cylindrical member described above, and may be formed in a columnar shape, and a plurality of columnar support members 23 may be provided at predetermined intervals along the external shape of the target T on the outer side of the target T when viewed in the direction of the center axis C. When the support member 23 is formed in the columnar shape and the plurality of columnar support members 23 is provided along the external shape of the target T, an attachment position of the sputter adjustment member 22 connected via the connecting member 24 can be easily changed. In this case, the number of the support members 23 may be two or more, but when the number of the support members 23 is four, for example, the attachment position of the sputter adjustment member 22 can be easily adjusted by the four columnar support members 23 so as to be provided substantially at the center of the target T.

### (Carrier)

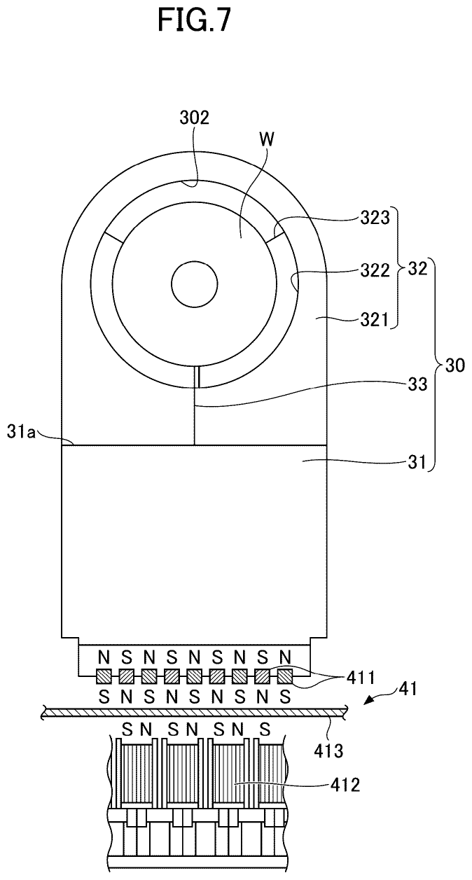

As illustrated in FIG. 1, the carrier 30 is provided inside the reaction chamber 10 and disposed at the central portion of the internal space S1. As illustrated in FIG. 7, the carrier 30 includes a support table 31 and a holder 32 attached to an upper portion of the support table 31. The substrate W is placed vertically on the holder 32, that is, the substrate W is held in a state where the principal surface of the substrate W is parallel to a direction of gravity. The carrier 30 may include two holders 32 arranged linearly on the upper portion of the support table 31 in the transport direction.

The support table 31 is formed of an elongated member made of an aluminum alloy, for example, and has a configuration that enables a permanent magnet 411 constituting a drive mechanism 41 of the transport mechanism 40 can be disposed on a lower surface of the support table 31.

The holder 32 is formed of a member made of an aluminum alloy, for example, and is attached to an attachment surface 31a formed by a flattened upper surface of the support table 31, using screws or the like.

The holder 32 includes a plate member 321, a hole 322 in which the substrate W is disposed on an inner side of the plate member 321, and a plurality of (three are illustrated in FIG. 7) support arms 323 attached to a wall of the plate member 321 defining a periphery of the hole 322. The support arms 323 are provided around the hole 322 at intervals, and are elastically deformable. The holder 32 is configured to detachably hold the substrate W placed inside the hole 322 in a state supported by the support arms 323, so that the outer peripheral portion of the substrate W makes contact with and is fitted into the support arms 323.

The plate member 321 has a thickness that is one to several times a thickness of the substrate W.

The thickness of the plate member 321 refers to a length in a direction perpendicular to a principal surface of the plate member 321. The thickness of the plate member 321 may be the thickness measured at an arbitrary location in a cross section of the plate member 321, or may be an average value of the thicknesses measured at several arbitrary locations. Hereinafter, the definition of the thickness is similarly applicable to other members.

The hole 322 in the plate member 321 is formed in a circular shape having a diameter slightly larger than the outer diameter of the substrate W.

The plurality of support arms 323 is attached to the periphery of the hole 322 to support the substrate W. Three support arms 323 are attached at predetermined intervals around the hole 322 of the plate member 321 so as to support the outer periphery of the substrate W disposed inside the hole 322 at three points. That is, the three support arms 323 support the substrate W at a lower fulcrum located at a lowermost position on the outer periphery of the substrate W, and at a pair of upper fulcrums located at upper symmetrical positions on the outer periphery of the substrate W with respect to a center line passing through the lower fulcrum along the direction of gravity.

Each support arm 323 may be formed of a leaf spring bent in an L-shape. Each support arm 323 is disposed with a base end thereof fixed to and supported by the holder 32, and a tip end thereof protruding toward the inside of the hole 322. Further, although not illustrated, a groove for engaging the outer peripheral portion of the substrate W may be provided at the tip end of each support arm 323.

The holder 32 is configured to detachably hold the substrate W in a state supported by the three support arms 323, so that the outer peripheral portion of the substrate W makes contact with and is fitted into the support arms 323. The substrate W can be attached to and detached from the holder 32 by pushing down the support arm 323 that supports the substrate W at the lower fulcrum.

The carrier 30 is provided with an electrode terminal 33 for applying a bias voltage to the substrate W held by the holder 32. The electrode terminal 33 is supported by the plate member 321 to be movable up and down (that is, movable in a vertical direction), and can come into contact with and separate from the outer peripheral portion of the substrate W held by the holder 32 from a lower side of the lower fulcrum.

In addition, as illustrated in FIG. 1, the carrier 30 has a guide rail 311 formed with a groove at a lower portion of the support table 31. A plurality of main bearings 421 of a guide mechanism 42 engages the groove of the guide rail 311.

### (Transport Mechanism)

As illustrated in FIG. 1, the transport mechanism 40 is provided inside the reaction chamber 10, and disposed below the carrier 30. The transport mechanism 40 includes the drive mechanism 41 that drives the carrier 30 in a non-contact manner, and the guide mechanism 42 that guides the carrier 30 that is transported.

As illustrated in FIG. 7, the drive mechanism 41 includes a plurality of permanent magnets 411 disposed below the carrier 30 so that the N-poles and the S-poles of the permanent magnets 411 are alternately arranged, a plurality of electromagnets 412 disposed below the permanent magnets 411 to face the permanent magnets 411 and arranged in the transport direction of the carrier 30, and a cover 413 that isolates the electromagnets 412 from the internal space S1 of the reaction chamber 10.

In order to ensure a high-speed response by the electromagnet 412, the permanent magnet 411 is preferably a ferrite magnet, a rare-earth magnet, or the like, for example, having large attraction and repulsion forces with respect to the electromagnet 412. A sintered magnet, such as a SmCo-based magnet, a NdFeB-based magnet, or the like is preferably used for the rare-earth magnet from a viewpoint of strengths of the attraction and repulsion forces. The ferrite magnet is easy to process and has a high toughness, and thus has an advantage in that it is easy to hold the ferrite magnet in a portion of the carrier 30 using screws or the like. Although the rare-earth magnet is difficult to process and is fragile, the rare-earth magnet has strong attraction and repulsion forces with respect to the electromagnet 412, and thus has an advantage in that the carrier 30 can be moved at a high speed. In a case where the rare-earth magnet is used as the permanent magnet 411, it is difficult to hold the magnet a portion of the carrier 30 using screws or the like. For this reason, it is preferable in this case to employ a structure in which a surface of the rare-earth magnet is covered with a nonmagnetic material, such as a stainless steel plate or the like, and the rare-earth magnet is embedded in the carrier 30.

The electromagnet 412 has a wire wound around a magnetic core in a coil shape, and the wire may be covered with a resin or the like in order to electrically insulate the wire. An electromagnet generally used in a sputtering apparatus, such as a magnetron sputtering apparatus or the like, can be used for the electromagnet 412.

The cover 413 with magnetic permeability covers an outer periphery of the electromagnet 412, and is formed to isolate the electromagnet 412 from the internal space S1 of the reaction chamber 10. By disposing the electromagnet 412 in a space formed by the magnetically permeable cover 413 in a state isolated from the internal space S1 of the reaction chamber 10, the electromagnet 412 during use will not be exposed to a space that assumes a vacuum state, such as the internal space S1. For this reason, even if the magnetic core and the wire constituting the electromagnet 412, the resin covering the wire, or the like are made of materials unsuitable for use in a vacuum environment, it is possible to prevent damage to the electromagnet 412. Alternatively, the electromagnet 412 may be disposed outside the reaction chamber 10 in a state exposed to the atmosphere.

The drive mechanism 41 can drive the carrier 30 in a non-contact manner while magnetically coupling the electromagnet 412 and the permanent magnet 411, by supplying electric power to the electromagnet 412.

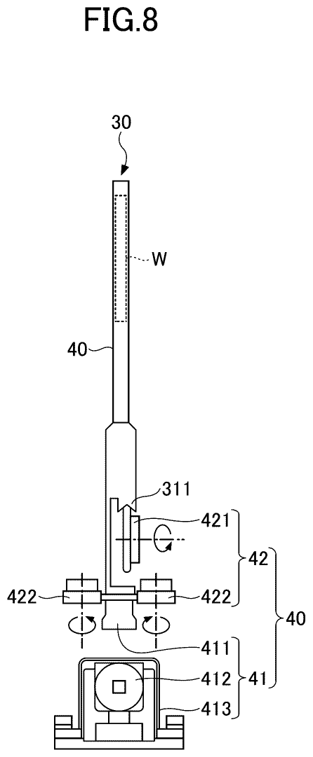

As illustrated in FIG. 8, the guide mechanism 42 includes the plurality of main bearings 421 supported rotatably around a horizontal axis, and the pair of sub bearings 422 supported rotatably around a vertical axis.

The plurality of main bearings 421 guides the carrier 30 in the vertical direction, and the main bearings 421 are linearly arranged side by side in the transport direction of the carrier 30.

The pair of sub bearings 422 guide the carrier 30 in the horizontal direction, and are disposed to oppose each other with the carrier 30 interposed therebetween. The sub bearings 422 are linearly arranged side by side in the transport direction of the carrier 30, similar to the main bearings 421.

The guide mechanism 42 guides the carrier 30 moving on the plurality of main bearings 421 in a state where the plurality of main bearings 421 engages the groove of the guide rail 311, and prevents the carrier 30 from tilting while the carrier 30 moves by sandwiching the carrier 30 between the pair of sub bearings 422.

The main bearings 421 and the sub bearings 422 are composed of rolling bearings, in order to reduce friction of mechanical components and ensure smooth rotational motion of the mechanical components. The rolling bearing is rotatably supported on a support shaft fixed to a frame (not illustrated) that is provided inside the reaction chamber 10.

In the sputtering apparatus 1, the substrate W is transported by the transport mechanism 40 to a position facing the target T inside the reaction chamber 10, and an inert gas is supplied from the gas inlet pipe 212 into the internal space S1 inside the reaction chamber 10 to make the internal space S1 an inert gas atmosphere set to a predetermined vacuum degree. Further, at the front surface of the target T, a magnetic field reaching the substrate W from the back surface of the target T and passing in a direction substantially parallel to the surface of the substrate W is generated by magnetic field lines in a closed loop of the magnet assembly 213 disposed on the back surface of the target T. A predetermined high voltage from an external power supply is applied to the target T via the backing plate 211, and the drive motor 214 is driven to drive and rotate the magnet assembly 213 disposed on the back surface of the target T via the rotating shaft 44a. By applying the predetermined high voltage to the target T, the inert gas introduced from the gas inlet pipe 212 is ionized to generate ionized atoms, and the generated ionized atoms collides with the front surface of the target T facing the substrate W, thereby knocking out electrons. The electrons that are knocked out from the front surface of the target T by the ionized atoms are confined by the magnetic field generated at the front surface of the target T by the magnet assembly 213, thereby generating high-density plasma in the reaction space R illustrated in FIG. 3 at the front surface of the target T. In a state where the plasma is generated, ionized atoms of the inert gas in the plasma collide with the front surface of the target T, thereby ejecting sputtered particles from the target T.

In this state, the drive motor 214 drives and rotates the magnet assembly 213, thereby varying the magnetic field passing through the hole 22a of the sputter adjustment member 22 and varying the magnetic flux, to generate the induced current. The distribution of the plasma generated in the reaction space R is varied by the generated induced current, and the plasma density near the inner peripheral portion of the substrate W can be reduced. Accordingly, the amount of sputtered particles deposited onto the inner peripheral portion of the substrate W is suppressed, and the sputtered particles are deposited on the surface of the substrate W while being dispersed from the inner peripheral portion to the outer peripheral portion of the substrate W, thereby forming a thin film. As a result, the thin film having a suppressed thickness variation and a highly uniform in-plane film thickness distribution from the inner peripheral portion to the outer peripheral portion of the substrate W can be formed on the surface of the substrate W.

In the sputtering apparatus 1 having the configuration described above, the sputter adjustment member 22 is provided on the center axis C between the substrate W and the target T, substantially at the center of the front surface of the target T. The sputter adjustment member 22 is made of a metal and is provided so that the hole 22a includes the center axis C. By rotating the magnet assembly 213 to generate the induced current in the sputter adjustment member 22, the distribution of the plasma generated in the reaction space R can be varied, and the plasma density near the inner peripheral portion of the substrate W in the reaction chamber 10 can be reduced. Accordingly, the sputtering apparatus 1 can suppress the amount of the sputtered particles deposited onto the inner peripheral portion of the substrate W, and relatively increase the amount of the sputtered particles deposited on the outer peripheral portion of the substrate W. Hence, the sputtering apparatus 1 can uniformly deposit the sputtered particles onto the inner peripheral portion and the outer peripheral portion of the substrate W, and can thus improve the uniformity of the in-plane film thickness distribution of the thin film formed on the substrate W.

In addition, the sputtering apparatus 1 can optimize the performance of an outer peripheral region of the substrate W by increasing the thickness of the outer peripheral portion of the substrate W to make the in-plane film thickness distribution of the substrate W uniform.

In the sputtering apparatus 1, the sputter adjustment member 22 is preferably formed of a ring-shaped member. When the ring-shaped member is used for the sputter adjustment member 22, the size of the hole 22a, such as the inner diameter of the sputter adjustment member 22 or the like, can be easily adjusted, and thus, the sputter adjustment member 22 can be easily formed to an optimal shape for the size of the substrate W. Hence, the sputtering apparatus 1 can appropriately vary the distribution of the plasma generated in the reaction space R by the sputter adjustment member 22 with respect to the substrate W, thereby reducing the plasma density near the inner peripheral portion of the substrate W inside the reaction chamber 10. As a result, the sputtering apparatus 1 can more accurately suppress the amount of sputtered particles deposited onto the inner peripheral portion of the substrate W depending on the type, size, or the like of the substrate W, and can thus easily achieve the uniformity of the in-plane film thickness distribution of the thin film formed on the substrate W.

In the sputtering apparatus 1, the inner diameter of the sputter adjustment member 22 is preferably smaller than the external shape (or the outer diameter) of the substrate W. Accordingly, the sputter adjustment member 22 can suppress the amount of sputtered particles deposited onto the inner peripheral portion of the substrate W, while allowing the sputtered particles from the target T to reach the entire surface of the substrate W. The sputtering apparatus 1 can thus form a thin film on the entire surface of the substrate W, while making the amount of sputtered particles deposited onto the inner peripheral portion and the outer peripheral portion of the substrate W uniform.

The sputter adjustment member 22 of the sputtering apparatus 1 is preferably provided substantially at the center of the target T when viewed in the direction of the center axis C. For this reason, the sputtering apparatus 1 can reliably dispose the sputter adjustment member 22 on the center axis C of the plasma generated in the reaction space R illustrated in FIG. 3 in the periphery of the target T. Hence, the sputtering apparatus 1 can increase the amount of sputtered particles deposited onto the outer peripheral portion of the substrate W while reliably suppressing the amount of sputtered particles deposited onto the inner peripheral portion of the substrate W. Accordingly, the sputtering apparatus 1 can reliably make the amount of sputtered particles deposited onto the inner peripheral portion and the outer peripheral portion of the substrate W uniform, and can thus reliably improve the uniformity of the in-plane film thickness distribution of the thin film formed on the substrate W.

The sputtering apparatus 1 preferably includes the support member 23 and the connecting member 24 between the target T and the substrate W. In this case, the sputter adjustment member 22 of the sputtering apparatus 1 can easily be positioned and provided on the center axis C. In addition, because the sputter adjustment member 22 can be easily attached and detached without significantly modifying the configuration inside the reaction chamber 10, the maintenance of the sputtering apparatus 1 can be easily performed.

As described above, the sputtering apparatus 1 can form a thin film having a highly uniform in-plane film thickness distribution on the substrate W. Hence, the sputtering apparatus 1 can be effectively used for forming a thin film as one or more layers constituting a magnetic recording medium that requires a highly uniform in-plane film thickness distribution of the layers, for example.

### <Thin Film Forming Method>

Next, a thin film forming method according to the present embodiment, which can be performed using the sputtering apparatus 1, will be described. The thin film forming method according to the present embodiment includes a thin film forming process (or step) of forming a thin film by depositing the sputtered particles of the target T onto the substrate W, using the magnetic field generated from the back surface side of the target T toward the substrate W that is provided to face the front surface of the target T.

In the thin film forming process, the magnetic field passing through the hole 22a of the sputter adjusting member 22 is varied by rotating the magnet assembly 213 provided on the back surface of the target T. The sputter adjustment member 22 is provided on the center axis C connecting the center of the target T and the center position of the substrate W between the target T and the substrate W, so that the hole 22a includes the center axis C. For this reason, by rotating the magnet assembly 213 to vary the magnetic field passing through the hole 22a of the sputter adjustment member 22, the sputtered particles to be deposited on the substrate W are dispersed from the inner peripheral portion to the outer peripheral portion of the substrate W, and deposited onto the substrate W.

In the thin film forming process of the thin film forming method according to the present embodiment, the thin film is formed in a state where the sputter adjustment member 22 is provided on the center axis C between the substrate W and the target T, substantially at the center of the front surface of the target T. The sputter adjustment member 22 is made of a metal and is provided so that the hole 22a includes the center axis C when viewed in the direction of the center axis C. For this reason, by rotating the magnet assembly 213 to generate the induced current in the sputter adjustment member 22, the distribution of the plasma generated in the reaction space R can be varied, and the plasma density near the inner peripheral portion of the substrate W inside the reaction chamber 10 can be reduced. Thus, in the thin film forming process, the amount of sputtered particles deposited on the inner peripheral portion of the substrate W can be suppressed, and the amount of sputtered particles deposited on the outer peripheral portion of the substrate W can be relatively increased. Hence, in the thin film forming method according to the present embodiment, because the amount of sputtered particles deposited onto the inner peripheral portion and the outer peripheral portion of the substrate W can be made uniform, the uniformity of the in-plane film thickness distribution of the thin film formed on the substrate W can be improved.

The thin film forming method according to the present embodiment can be performed using the sputtering apparatus 1, and can be effectively used for forming a thin film as one or more layers constituting the magnetic recording medium that requires a highly uniform in-plane film thickness distribution of the layers, for example. Accordingly, the thin film forming method according to the present embodiment can be effectively used in a method for manufacturing a magnetic recording medium in which the layer constituting the magnetic recording medium is formed to manufacture the magnetic recording medium.

### <Apparatus for Manufacturing Magnetic Recording Medium>

Next, an apparatus for manufacturing a magnetic recording medium, which may be applied with the sputtering apparatus according to the present embodiment, will be described. In the present embodiment, an in-line film forming apparatus that performs a film forming process while sequentially transporting a substrate to be processed among a plurality of film forming chambers to manufacture a magnetic recording medium to be installed in a magnetic storage apparatus (or a magnetic recording and/or reproducing apparatus) will be described as an example of the apparatus for manufacturing the magnetic recording medium.

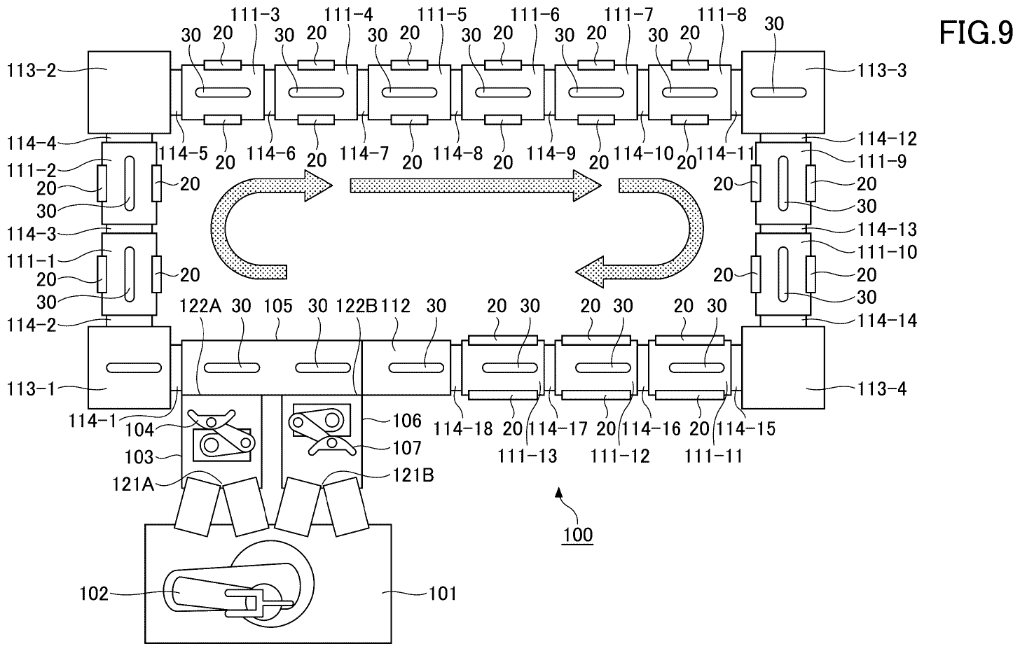

FIG. 9 is a diagram illustrating an example of a configuration of the in-line film forming apparatus applied with the sputtering apparatus according to the present embodiment. As illustrated in FIG. 9, an in-line film forming apparatus 100 includes a substrate transferring robot chamber 101, a substrate transferring robot 102 installed on the substrate transferring robot chamber 101, and a substrate mounting robot chamber 103 adjacent to the substrate transferring robot chamber 101. The in-line film forming apparatus 100 also includes a substrate mounting robot 104 disposed inside the substrate mounting robot chamber 103, a substrate exchanging chamber 105 adjacent to the substrate mounting robot chamber 103, a substrate removing robot chamber 106 adjacent to the substrate exchanging chamber 105, and a substrate removing robot 107 disposed inside the substrate removing robot chamber 106. The in-line film forming apparatus 100 further includes a plurality of processing chambers 111-1 through 111-13 and a preliminary chamber 112 arranged in parallel between an entrance side and an exit side of the substrate exchanging chamber 105, a plurality of corner chambers 113-1 through 113-4, and a plurality of carriers 30 sequentially transferred among the processing chambers 111-1 through 111-13, the preliminary chamber 112, and the corner chambers 113-1 through 113-4 from the entrance side to the exit side of the substrate exchanging chamber 105.

Gate valves 114-1 through 114-18 that can be opened and closed are provided between the respective chambers from an inlet side to an outlet side of the substrate exchanging chamber 105. The processing chambers 111-1 through 111-13 and the preliminary chamber 112 can form independent sealed spaces by closing the gate valves 114-1 through 114-18.

The substrate transferring robot 102 supplies the substrate W from a cassette (not illustrated) accommodating the substrate W before being subjected to the film forming process to the substrate mounting robot chamber 103, and recovers the substrate W after being subjected to the film forming process from the substrate removing robot chamber 106.

Further, gates 121A and 121B which can be opened and closed are provided between the substrate transferring robot chamber 101 and the substrate mounting robot chamber 103 and between the substrate transferring robot chamber 101 and the substrate removing robot chamber 106, respectively. Further, gates 122A and 122B which can be opened and closed are provided between the substrate exchanging chamber 105 and the substrate mounting robot chamber 103 and between the substrate exchanging chamber 105 and the substrate removing robot chamber 106, respectively.

The substrate mounting robot 104 mounts the substrate W before being subjected to the film forming process on the carrier 30 inside the substrate exchanging chamber 105.

The substrate removing robot 107 removes the substrate W after being subjected to the film forming from the carrier 30 inside the substrate exchanging chamber 105.

The plurality of processing chambers 111-1 through 111-13 and the preliminary chamber 112 basically have the same configuration as the reaction chamber 10 of the sputtering apparatus 1, and the processing modules 20 corresponding to the processing contents for the substrate W held by the carrier 30 are disposed on both side surfaces of each of the processing chambers 111-1 through 111-13.

Although not illustrated, the first vacuum pump 18 and the second vacuum pump 19 illustrated in FIG. 1 are connected as vacuum pumps to the processing chambers 111-1 to 111-13 and the preliminary chamber 112, and the processing chambers 111-1 through 111-13 and the preliminary chamber 112 can be individually evacuated under reduced pressure by operations of the vacuum pumps.

In addition, a rotating mechanism (not illustrated) for changing a moving direction of the carrier 30 is provided in each of the corner chambers 113-1 through 113-4.

The in-line film forming apparatus 100 is configured to perform the film forming process on the substrate W illustrated in FIG. 1 held by each carrier 30 while sequentially transferring the plurality of carriers 30 among the respective processing chambers 111-1 through 111-13, the preliminary chamber 112, and the corner chambers 113-1 through 113-4 from the entrance side to the exit side of the substrate exchanging chamber 105.

The in-line film forming apparatus 100 can form each layer constituting the magnetic recording medium with a high uniformity of the in-plane film thickness distribution, and can thus manufacture a high-quality magnetic recording medium with high uniformity of the in-plane film thickness distribution.

In addition, because the in-line film forming apparatus 100 can transport the carrier 30 at a high speed by the transport mechanism 40 described above, it is possible to increase a productivity of the magnetic recording medium by manufacturing the magnetic recording medium using the in-line film forming apparatus 100.

### <Method for Manufacturing Magnetic Recording Medium>

Next, a method for manufacturing a magnetic recording medium according to the present embodiment will be described. In the method for manufacturing the magnetic recording medium according to the present embodiment, a stack is formed by sequentially stacking a magnetic layer and a protective layer on both surfaces of the substrate W while sequentially transferring a nonmagnetic substrate serving as the substrate W held by the carrier 30 between the plurality of processing chambers 111-1 through 111-13 using the in-line film forming apparatus 100. The magnetic layer may include a soft magnetic layer, an intermediate layer, and a recording magnetic layer that are sequentially stacked. In the method for manufacturing the magnetic recording medium according to the present embodiment, the magnetic recording medium is manufactured by forming the stack using the in-line film forming apparatus 100 and then forming a lubricant film on both outermost surfaces of the stack, which is the substrate W after being subjected to the film forming process, using a coating apparatus (not illustrated).

The method for manufacturing the magnetic recording medium according to the present embodiment can manufacture a high-quality magnetic recording medium having a high uniformity of the in-plane film thickness distribution, using the in-line film forming apparatus 100.

In addition, in the method for manufacturing the magnetic recording medium according to the present embodiment, a production capacity of the magnetic recording medium can be increased by using the in-line film forming apparatus 100.

### (Magnetic Recording Medium)

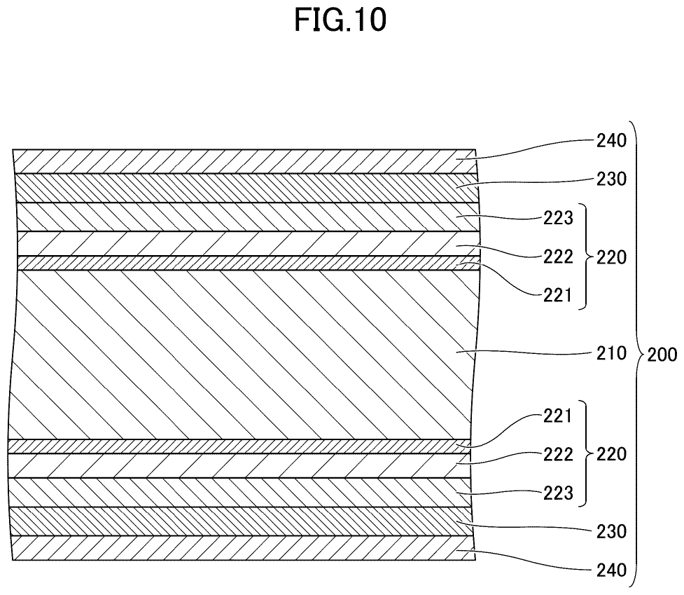

The magnetic recording medium manufactured by the apparatus for manufacturing the magnetic recording medium, applied with the sputtering apparatus according to the present embodiment, will be described. FIG. 10 is a cross sectional view illustrating an example of a layer structure of the magnetic recording medium manufactured by the apparatus for manufacturing the magnetic recording medium described above. As illustrated in FIG. 10, a magnetic recording medium 200 includes a magnetic layer 220, a protective layer 230, and a lubricant film 240 stacked in this order on both surfaces of a nonmagnetic substrate 210 serving as the substrate W, for example. The magnetic layer 220 includes a soft magnetic layer 221, an intermediate layer 222, and a recording magnetic layer 223, and has a stacked structure (or a multi-layer structure) in which these layers are stacked in this order on the nonmagnetic substrate 210.

An arbitrary nonmagnetic substrate, such as substrates made of an Al alloy including Al as a main component, such as an Al—Mg alloy or the like, substrates made of soda glass, aluminosilicate glass, crystallized glass, silicon, titanium, and ceramics, and substrates made of various kinds of resins, for example, can be used for the nonmagnetic substrate 210. Among these substrate, an Al alloy substrate made of an Al alloy, a glass substrate made of crystallized glass, or a silicon substrate made of silicon are preferably used for the nonmagnetic substrate 210. An average surface roughness (Ra) of these substrates is preferably 1 nm or less, more preferably 0.5 nm or less, and still more preferably 0.1 nm or less.

The magnetic layer 220 may be an in-plane magnetic layer for an in-plane magnetic recording medium or a perpendicular magnetic layer for a perpendicular magnetic recording medium, but is preferably a perpendicular magnetic layer in order to achieve a high recording density. In addition, the magnetic layer 220 is preferably formed using an alloy including Co as a main component. For example, the magnetic layer 220 for the perpendicular magnetic recording media may be a stack of the soft magnetic layer 221 made of a soft magnetic alloy, such as a FeCo alloy, a FeTa alloy, and a Co alloy, the intermediate layer 222 made of Ru or the like, and a recording magnetic layer 223 made of a 60Co-15Cr-15Pt alloy or a 70Co-5Cr-15Pt-10SiO₂ alloy.

Examples of the soft magnetic FeCo alloy include FeCoB, FeCoSiB, FeCoZr, FeCoZrB, FeCoZrBCu, or the like, for example. Examples of the soft magnetic FeTa alloy include FeTaN, FeTaC, or the like, for example. Examples of the soft magnetic Co alloy include CoTaZr, CoZrNB, CoB, or the like, for example.

A total thickness of the magnetic layer 220 may be selected to obtain sufficient head input and output according to a type of magnetic alloy used and a type of the stacked structure of the magnetic layer 220. The total thickness of the magnetic layer 220 may be in a range of 3 nm to 20 nm, or in a range of 5 nm to 15 nm, for example. The total thickness of the magnetic layer 220 may be appropriately set within a range in which an output of a certain level or higher is obtainable during reproduction and various parameter values indicating recording and reproducing characteristics can be maintained.

The protective layer 230 may be made of a material that is generally used in magnetic recording media, and examples of such a material include carbon (C), carbon-based materials, such as hydrocarbon (HXC), nitrogenated carbon (CN), amorphous carbon, silicon carbide (SiC), or the like, SiO₂, Zr₂O₃, TiN, or the like, for example. The protective layer 230 may be a stack of two or more layers, that is, the protective layer 230 may have a multi-layer structure. A thickness of the protective layer 230 is preferably less than the 10 nm, for example, from a viewpoint of reducing a distance between the magnetic head and the magnetic layer 220 and obtaining sufficient input-output characteristics.

The lubricant film 240 can be formed by coating a fluorine-based liquid lubricant such as perfluoroether (PFPE), a solid lubricant such as fatty acid, or the like on the protective layer 230. A thickness of the lubricant film 240 is usually in a range of 1 nm to 4 nm. A general coating method known in the related art, such as a dipping, spin-coating, or the like, may be used for the lubricant coating method.

### (Magnetic Storage Apparatus)

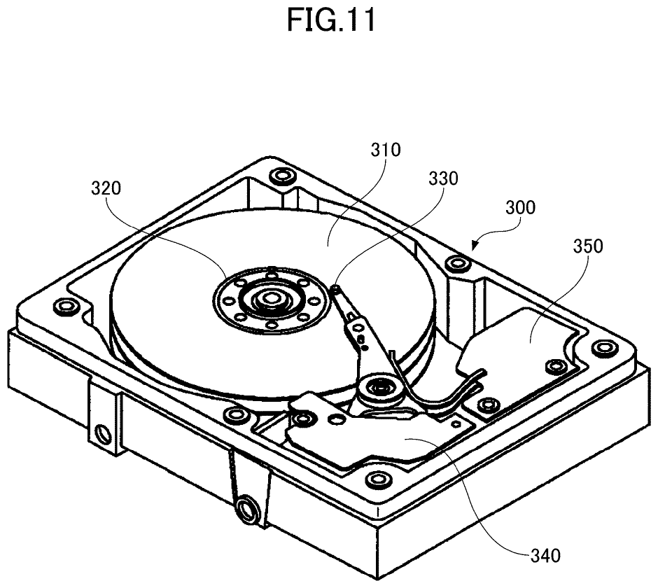

A hard disk drive (HDD) is an example of a magnetic storage apparatus (or a magnetic recording and/or reproducing apparatus) using the magnetic recording medium 200 described above, for example. FIG. 11 illustrates an example of the magnetic storage apparatus using the magnetic recording medium 200. As illustrated in FIG. 11, a HDD 300 includes a magnetic disk 310 formed by the magnetic recording medium 200 illustrated in FIG. 10, a medium drive 320 that drives and rotates the magnetic disk 310, a magnetic head 330 that performs a recording operation and a reproducing operation on the magnetic disk 310, a head drive 340 that moves the magnetic head 330 in a radial direction of the magnetic disk 310, and a signal processing circuit 350. The signal processing circuit 350 processes input data to send a recording signal to the magnetic head 330, and processes a reproduced signal from the magnetic head 330 to output data.

Because the HDD 300 uses a high-quality magnetic recording medium having a highly uniform in-plane film thickness distribution as the magnetic disk 310, the data can be stably input and output, and stable information writing and reading performance can be achieved, so that a product reliability of the HDD 300 can be further improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

Hereinafter, the embodiment will be described in more detail with reference to an exemplary implementation and a comparative example, but the embodiment is not limited to the exemplary implementation and the comparative example.

### <Preparation of Samples>

### [Exemplary Implementation]

A sample according to the exemplary implementation was prepared by forming a film of NiW as a magnetic material on an aluminum substrate having an outer diameter of 97 mm, an inner diameter of 25 mm, and a thickness of 0.5 mm, using the sputtering apparatus 1 illustrated in FIG. 1. The sputter adjustment member 22 was a ring-shaped member having the hole 22a with a diameter of 30 mm, formed by winding a metal wire made of Cu in a ring shape. The sputter adjustment member 22 was provided at a position at a distance of 16 mm from the center of the front surface of the target T of the sputtering apparatus 1 illustrated in FIG. 1. A distance between the target T and the substrate W was set to 11.75 mm. Sputtering conditions for forming the magnetic material using the sputtering apparatus 1 illustrated in FIG. 1 were as follows.

### (Sputtering Conditions)

Target composition used: NiW
Inert gas: Ar gas
Gas pressure: 1.5 Pa
Rotary magnetron cathode (RMC): 600 rpm
Deposition condition: 600 W×30 seconds

### Comparative Example

A sample was prepared in the same manner as in the exemplary implementation described above, except that the sputter adjustment member 22 was not used.

### <Evaluation of In-Plane Film Thickness Distribution of Front Surface and Back Surface of Samples>

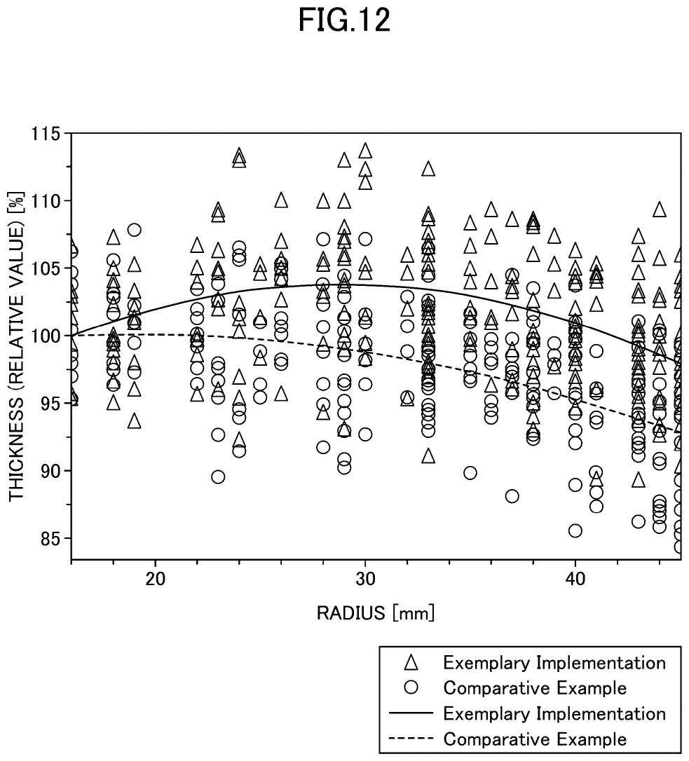

The in-plane thicknesses at the front surface and the back surface of the manufactured samples were measured using an X-ray fluorescence analyzer (Wafer/Disk Analyzer 3640 manufactured by Rigaku Holdings Corporation), and the in-plane film thickness distributions were evaluated. FIG. 12 is a diagram illustrating measurement results of the thickness measured at predetermined lengths in a radial direction on the front surface and the back surface of the samples of the exemplary implementation and the comparative example. In FIG. 12, the thicknesses of the following measurement points at each radius were averaged and plotted as a quadratic curve. The thickness at each radius is illustrated as a relative value normalized to a mean of 100 for the value of the quadratic curve with the radius of 16 mm. The film thickness distribution was derived from the following formula (1) based on the quadratic curve obtained by averaging the thicknesses.

### (Measurement Points)

R=16 mm: 8 points at intervals of 45°
R=18 mm: 12 points at intervals of 30°
R=19 mm: 8 points at intervals of 45°
R=22 mm: 8 points at intervals of 45°
R=23 mm: 8 points at intervals of 45°
R=24 mm: 8 points at intervals of 45°
R=25 mm: 4 points at intervals of 90°
R=26 mm: 16 points at intervals of 45°
R=28 mm: 8 points at intervals of 45°
R=29 mm: 16 points at intervals of 22.5°
R=30 mm: 8 points at intervals of 45°
R=32 mm: 4 points at intervals of 90°
R=33 mm: 24 points at intervals of 15°
R=35 mm: 8 points at intervals of 45°
R=36 mm: 8 points at intervals of 45°
R=37 mm: 8 points at intervals of 45°
R=38 mm: 16 points at intervals of 22.5°
R=39 mm: 4 points at intervals of 90°
R=40 mm: 16 points at intervals of 22.5°
R=41 mm: 8 points at intervals of 45°
R=43 mm: 24 points at intervals of 15°
R=44 mm: 16 points at intervals of 22.5°
R=45 mm: 20 points at intervals of 18° Total: 252 points

### (Film Thickness Distribution)

$$Film thickness distribution [ \% ] = \{ ( maximum value - minimum value ) / maximum value \} \times 100 \qquad ( 1 )$$

As illustrated in FIG. 12, a difference in the thicknesses between the inner peripheral portion and the outer peripheral portion was small between the front surface and the back surface of the sample of the exemplary implementation, and the thickness between the inner peripheral portion and the outer peripheral portion increased. The film thickness distribution of the sample of the exemplary implementation was approximately 5.7%. In contrast, the thickness at the front surface and the back surface of the sample of comparative example decreased from the inner peripheral portion toward the outer peripheral portion, and the film thickness distribution of the sample of comparative example was approximately 7.38. Accordingly, the sample of the exemplary implementation had a smaller difference in the thicknesses between the inner peripheral portion and the outer peripheral portion at the front surface and back surface of the sample, and a higher uniformity of the in-plane film thickness distribution, as compared to the sample of the comparative example.

Therefore, it may be regarded that the sputtering apparatus according to the present embodiment can manufacture a magnetic recording medium with enhanced uniformity of the in-plane film thickness distribution of each layer constituting the magnetic recording medium, and can manufacture a magnetic recording medium with a high uniformity of the in-plane film thickness distribution at the front surface and the back surface of the substrate.

According to an aspect of the present disclosure, it is possible to improve the uniformity of the in-plane film thickness distribution of the thin film formed on the substrate.

What is claimed is:

1. A sputtering apparatus configured to form a thin film by depositing sputtered particles of a target on a substrate, using a magnetic field generated from a back surface side of the target toward the substrate provided to face a front surface of the target, the sputtering apparatus comprising:
a magnetic field generator provided on the back surface of the target;
a rotor configured to rotate the magnetic field generator; and
a cylindrical sputter adjustment member provided between the target and the substrate on a center axis connecting a center of the target and a center position of the substrate,
wherein the sputter adjustment member is made of a metal, and includes a hole located at a position including the center axis.

2. The sputtering apparatus as claimed in claim 1, wherein the sputter adjustment member is composed of a ring-shaped member including a metal wire wound in a ring shape.

3. The sputtering apparatus as claimed in claim 1, wherein an inner diameter of the sputter adjustment member is smaller than an outer diameter of the substrate.

4. The sputtering apparatus as claimed in claim 1, wherein the hole of the sputter adjustment member is provided at a central portion of the target when viewed in a direction of the center axis.

5. The sputtering apparatus as claimed in claim 1, wherein the thin film constitutes a magnetic recording medium.

6. An apparatus for manufacturing a magnetic recording medium, comprising:
the sputtering apparatus as claimed in claim 1,
wherein the sputtering apparatus forms the thin film constituting a layer of the magnetic recording medium.

7. A thin film forming method comprising:
forming a thin film by depositing sputtered particles of a target on a substrate, using a magnetic field generated from a back surface side of the target toward the substrate provided to face a front surface of the target,
wherein the forming includes rotating a magnetic field generator provided on the back surface of the target to vary a magnetic field passing through a hole in a cylindrical sputter adjustment member provided between the target and the substrate on a center axis connecting a center of the target and a center position of the substrate, the sputter adjustment member being made of a metal and includes the hole located at a position including the center axis.

8. A method for manufacturing a magnetic recording medium, comprising:
forming the thin film on the substrate, as a layer constituting a magnetic recording medium, using the thin film forming method as claimed in claim 7.
